(19) United States
(12) Patent Application Publication
(10) Pub. No.: US 2021/0367172 A1
(43) Pub. Date: Nov. 25, 2021

(54) DEVICE HAVING RESIN SUBSTRATE AND MANUFACTURING METHOD THEREOF

(71) Applicant: Japan Display Inc., Tokyo (JP)

(72) Inventor: Hiroshi KAWANAGO, Tokyo (JP)

(73) Assignee: Japan Display Inc., Tokyo (JP)

(21) Appl. No.: 17/391,518

(22) Filed: Aug. 2, 2021

Related U.S. Application Data
(63) Continuation of application No. PCT/JP2020/005979, filed on Feb. 17, 2020.

(30) Foreign Application Priority Data
Feb. 19, 2019 (JP) 2019-027234

(51) Int. Cl. H01L 51/00; C03C 27/04; C03C 17/42

(52) U.S. Cl. CPC H01L 51/0097; C03C 27/046; C03C 17/42; C03C 2217/77; H01L 51/003; C03C 2217/213; C03C 2218/328; H01L 51/0014

(57) ABSTRACT

The purpose of the invention is to manufacture the device having a resin substrate without using expensive machine like laser apparatus and so forth, and to raise a yield rate of the material. The structure is as follows.

A device having a resin substrate:

in which the resin substrate has a surface, on which a functional layer is formed, and a back surface, which is rear side from the surface,

the back surface has a peripheral area and an inner area, which is located inner side than the peripheral area in a plan view,

the peripheral area has a rough surface whose surface roughness is larger compared with a surface roughness of the inner area.

The present application is a continuation application of International Application No. PCT/JP2020/005979, filed on Feb. 17, 2020, which claims priority to Japanese Patent Application No. 2019-027234, filed on Feb. 19, 2019. The contents of these applications are incorporated herein by reference in their entirety.

### BACKGROUND OF THE INVENTION

### (1) Field of the Invention

The present invention relates to display devices, specifically flexible display devices that the substrates can be curved, and manufacturing method for those display devices.

### (2) Description of the Related Art

The organic EL display device and the liquid crystal display device can be used in curved state by making those devices thin. Further, those display devices can be made flexible by making the substrates from resin, e.g. polyimide. Since the organic EL display devices do not need back lights, they have merit to be made thin.

If the resin substrate is made as thin as 10 to 20 microns, the display device can be made flexible; however, such a thin substrate is difficult to go through the manufacturing process. Therefore, such a resin substrate is formed on the glass substrate of a thickness of 0.5 or 0.7 mm to go through the manufacturing process, and the display elements are formed on the thin resin substrate. The laser is applied for laser abrasion to the interface between the glass substrate and the resin substrate to separate the glass substrate from the resin substrate.

Patent document 1 discloses the technology to separate the glass substrate from the resin substrate with laser.

### PATENT DOCUMENT

Patent document 1: WO 2005/050754

Patent document 2: Japanese patent application laid open No. 2010-67957

Patent document 3: Japanese patent application laid open No. 2013-168445

### SUMMARY OF THE INVENTION

A separation process using laser has following problems. Firstly, the laser machine is expensive. Secondly, a controlling is difficult to align the laser irradiation precisely at an interface between the glass substrate and the resin substrate, consequently, the yield rate in the manufacturing process is decreased.

Patent document 2 and Patent document 3 disclose the following method to separate the glass substrate from the resin substrate without using laser. Namely, a separation layer, from which the resin is easily separated from the glass substrate, is formed on the glass substrate at the area which does not correspond to the peripheral region of the resin substrate. The peripheral region of the resin substrate adheres to the glass substrate firmly, thus, adherence between the glass substrate and the resin substrate is maintained during the manufacturing process. In the final manufacturing process, the region in which the glass substrate and the resin substrate adhere to each other is removed. After the removal, the glass substrate and the resin substrate adhere to each other only at separation layer, thus, the resin substrate is easily separated from the glass substrate. Among the references, Patent document 3 further discloses to recycle the glass substrate.

In Patent document 2 and Patent document 3, the mother substrate must be laid out to secure the extra adhesion area for adhesion with the glass substrate; therefore, there is a problem of the yield rate of the material.

The purpose of the present invention is to realize a manufacturing method in which a laser machine or other expensive machines are not necessary, and the yield rate of the material can be raised.

The present invention overcomes the above explained problems; the concrete structures are as follows.

(1) A device having a resin substrate:

in which the resin substrate has a surface, on which a functional layer is formed, and a back surface, which is rear side from the surface,

the back surface has a peripheral area and an inner area, which is located inner side than the peripheral area in a plan view,

the peripheral area has a rough surface whose surface roughness is larger compared with a surface roughness of the inner area.

(2) A manufacturing method of a device having a resin substrate including:

forming a first layer, which is made of metal or metal oxide on a glass substrate,

forming a second layer, which is made of metal or metal oxide, on the first layer,

forming a third layer, which is made of metal or metal oxide, on the second layer,

patterning the third layer,

forming a resin substrate on the third layer,

forming a functional layer on the resin substrate,

after that, peeling off the resin substrate from the second layer and the third layer.

### BRIEF DESCRIPTION OF THE DRAWINGS

FIG. 1 is a plan view of an organic EL display device;

FIG. 2 is a cross sectional view of a display area of the organic EL display device;

FIG. 3 is a cross sectional view of a mother substrate;

FIG. 4 is a cross sectional view of FIG. 3 along the line A-A;

FIG. 5 is a table that shows the constitution of a first layer, a second layer and a third layer;

FIG. 6 is a cross sectional view in which a polyimide substrate is formed on the structure of FIG. 4;

FIG. 7 is a cross sectional view in which an organic EL layer is formed on the structure of FIG. 6;

FIG. 8 is a plan view of the mother substrate;

FIG. 9 is a cross sectional view of the individual organic EL display device, which is separated from the mother substrate;

FIG. 10 is a cross sectional view, in which the organic EL display device is being separated from the glass substrate;

FIG. 11 is a plan view of a back surface of the polyimide substrate;

FIG. 12 is a cross sectional view corresponding to the line B-B of FIG. 11;

FIG. 13 is an another example of a cross sectional view of the individual organic EL display device, which is separated from the mother substrate;

FIG. 14 is a cross sectional view, in which the organic EL display device is being separated from the glass substrate in another example;

FIG. 15 is a plan view of another example of the third layer;

FIG. 16 is a plan view of still another example of the third layer;

FIG. 17 is a plan view of still another example of the third layer;

FIG. 18 is a plan view of still another example of the third layer;

FIG. 19 is a plan view of still another example of the third layer; and

FIG. 20 is a plan view of still another example of the third layer.

### DETAILED DESCRIPTION OF THE PREFERRED EMBODIMENTS

The present invention is explained by the following embodiments. Although the following embodiments are explained for the structure of the organic EL display device, however, the present invention is applicable to other display devices having resin substrates as e.g. the liquid crystal display device.

### Embodiment 1

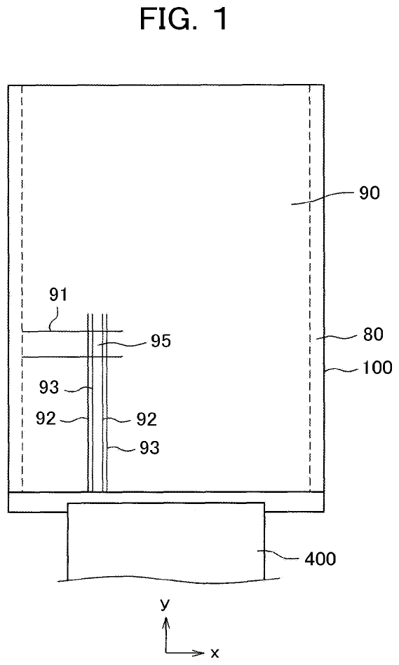

FIG. 1 is a plan view of the organic EL display device, to which the present invention is applied. The organic EL display device according to the present invention is the display device that can be curved flexibly. Accordingly, the TFT substrate 100 is made of resin, on which the TFTs (Thin Film Transistors), scan lines, power lines, video signal lines, pixel electrodes, organic EL layers and so forth are formed.

In FIG. 1, the scan line driving circuits 80 are formed at both sides of the display area 90. In the display area 90, the scan lines 91 extend in lateral direction (x direction) and arranged in longitudinal direction (y direction). The video signal lines 92 and the power lines 93 extend in the longitudinal direction and arranged in lateral direction. The pixel 95 is defined by area surrounded by scan lines 91 and the video signal lines 92 or the power lines 93. In the pixel 95, the driving transistor, the switching transistor, (each of them is formed by TFT), the organic EL layer that emits light, and so forth are formed.

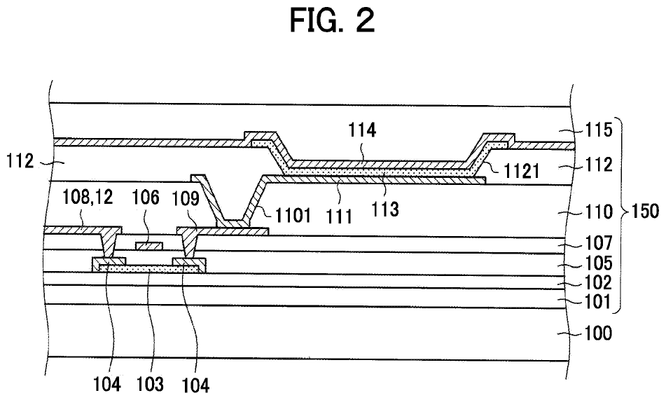

FIG. 2 is a cross sectional view of the display area of the organic EL display device shown in FIG. 1. In FIG. 2, the TFT substrate 100 is formed from resin. Among resin, polyimide has superior characteristics, as heat resistant property, mechanical strength and so forth, for the substrate of the display device. Therefore, the resin of the resin substrate 100 means polyimide in the following embodiments, however, the present invention is applicable when the TFT substrate is made of resin other than polyimide. By the way, the TFT substrate 100 may be referred to as the polyimide substrate 100. A thickness of the TFT substrate 100 is e.g. 10 to 20 microns.

The polyimide film 101 is formed on the polyimide substrate 100 in a thickness of 2 to 3 microns to make the surface further flatten. The inorganic undercoat film 102 is formed on the polyimide film 101 to protect the organic EL layer from moisture and other impurities invading through the resin substrate 100. The oxide semiconductor 103, which constitutes the switching TFT, is formed on the inorganic undercoat 102. The connecting electrodes 104, formed from Ti or MoW, are formed on the drain portion and the source portion of the oxide semiconductor 103 to protect the oxide semiconductor 103.

The gate insulating film 105 is formed covering the oxide semiconductor 103; the gate electrode 106 is formed on the gate insulating film 105. The interlayer insulating film 107 is formed covering the gate electrode 106; the drain electrode 108 and the source electrode 109 are formed on the interlayer insulating film 107. The drain electrode 108 connects the oxide semiconductor 103 with the video signal line 92. The source electrode 109 connects the oxide semiconductor 103 with the lower electrode 111 for the organic EL layer 113.

The organic passivation film 110 is formed, in a thickness of 2 to 3 microns, covering the drain electrode 108 and the source electrode 109. Polyimide or acrylic resin and so forth are used for the organic passivation film 110. The through hole 1101 is formed in the organic passivation film 110 to connect the source electrode 109 with the lower electrode 111. The lower electrode 111 has a two layer structure; the lower layer is a reflection electrode made of metal and the upper layer is an anode made of ITO (Indium Tin Oxide).

The bank 112 is formed covering the periphery of the lower electrode 111. The resin, as polyimide or acrylic resin and so forth, is formed all over the display area, then, holes 1121 are formed in the resin at the places corresponding to the lower electrodes 111. The bank 112 is formed between the holes 1121. The organic EL layer 113, as the light emitting layer, is formed in the hole 1121, then the upper electrode 114 is formed from transparent conductive film as ITO. The upper electrode 113 is formed all over the display area.

The protective film 115 is formed on the upper electrode 114 to protect the organic EL layer 113 from e.g. external moisture. The protective layer 115 is e.g. a laminated film of an inorganic film like SiN and an organic film of e.g. polyimide or acrylic resin.

The organic EL display devices explained in FIGS. 1 and 2 having resin substrates 100 formed from e.g. polyimide of a thickness of 10 to 20 microns are very flexible display devices. The organic EL display devices having such a thin film substrate 100 are formed as the following manufacturing process.

The material for the polyimide containing polyamic acid is coated with e.g. slit coater on the mother glass substrate on which many organic EL display devices are to be formed. The material for the polyimide is e.g. SEMICOFINE SP-020 of Toray Industries Incorporation; specific ingredients are 85% of N-Methyl Pyrrolidone and 15% of Polyamic Acid. Among them, the polyamic acid is transformed to polyimide through imidization. The material is coated on the mother glass substrate so that the TFT substrate 100 of polyimide becomes approximately 10 microns after baking.

The organic EL display device is completed after the structure of FIG. 2 is formed on the TFT substrate 100 formed from polyimide. In this state, many organic EL display devices are formed on the mother glass substrate; this is referred to as the mother panel in this specification. After that, individual organic EL display devices are separated from the mother panel; then, the glass substrate is removed from the individual organic EL display device including the resin substrate. The present invention is regard to a method for removing the glass substrate from the resin substrate.

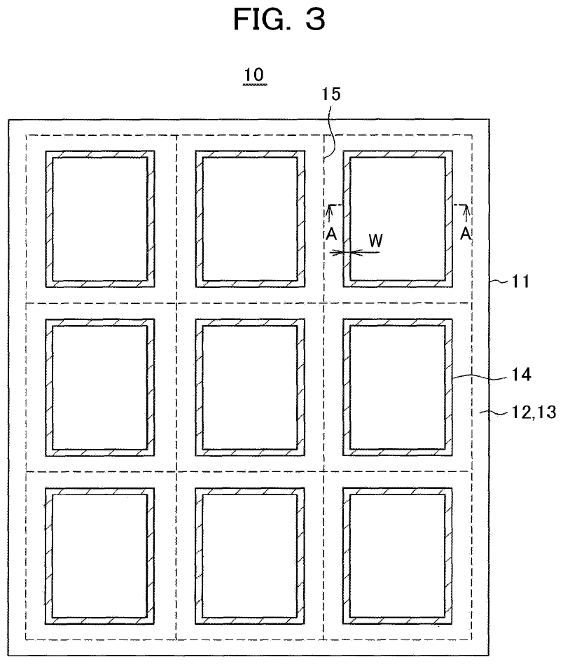

FIG. 3 is a plan view of the mother substrate 10; three metal layers are formed on the mother glass substrate 11 to separate the organic EL display device from the glass substrate on the mother glass substrate 11. Many organic EL display devices are to be formed on the mother substrate 10. In this specification, a large size glass substrate, on which many organic EL display devices are to be formed, is referred to as the mother glass substrate 11; the mother substrate 10 is defined as that three metal layers are formed on the mother glass substrate 11; the mother panel 20 is defined as that many organic EL display devices are formed on the mother substrate 10.

In FIG. 3, the first layer 12, the second layer 13, the third layer 14 made of metal or metal oxide are formed on the mother glass substrate 11. Incidentally, metal includes metal alloy in this specification. The first layer 12, the second layer 13 are formed in this order in plane on all over the mother glass substrate 11. The broken lines are imaginary lines on which individual organic EL display devices are to be separated from the mother panel 20, in which many organic EL display devices have been formed. The third layer 14 is formed in frame shape along the periphery of the individual organic EL display device.

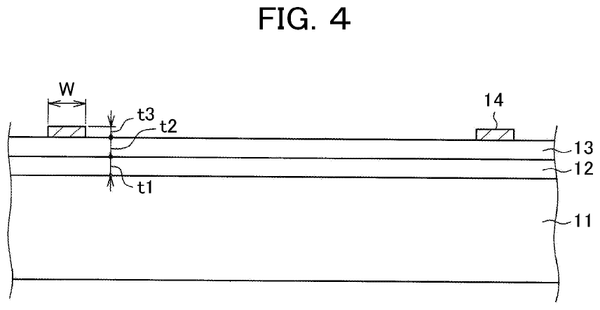

FIG. 4 is a cross sectional view of FIG. 3 along the line A-A. In FIG. 4, the first layer 12 is formed on the mother glass substrate 11 in planar shape, the second layer 13 is formed on the first layer 12, and the third layer 14 is formed in narrow stripe shapes on the second layer 13. The first layer 12 and the second layer 13 are formed all over the mother glass substrate 11. The third layer 14 is formed on all over the mother glass substrate 11, then, is patterned by e.g. etching.

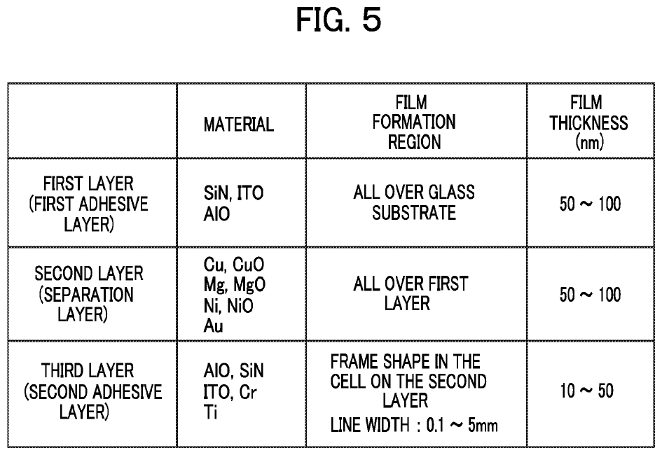

The first layer 12 may be referred to as the first adhesive layer in this specification. The first layer 12 has a large adhesive strength with both the lower layer of glass substrate 11 and the upper layer of second layer 13. As shown in FIG. 5, SiN, ITO, AlO and so forth are used for the first layer 12. The first layer 12 is formed by e.g. sputtering in a thickness t1 of 50 to 100 nm.

The adhesive strength between the first layer 12 and the glass substrate 11 and between the first layer 12 and the second layer 13 is stronger than the peel off strength between the second layer 13 and the organic E1 display device, and between the third layer 14 and the organic EL display device. In other words, the total adhesive strength between the organic EL display device and the second layer 13, and between the organic EL display device and the third layer 14 is smaller than an adhesive strength between the glass substrate 11 and the first layer 12, and between the first layer 12 and the second layer 13.

The second layer 13 is formed on the first layer 12 on all over the mother glass substrate 11. The second layer 13 is also referred to as a separation layer 13 in this specification. The second layer 13 has a strong adhesive strength with the first layer 12, which is a lower layer, however, it has a weak adhesive strength with the resin substrate 100, which is an upper layer; thus, the resin substrate 100 can be peeled off easily from the second layer 13. As shown in FIG. 5, the material for the second layer 13 is made of e.g. Cu, CuO, Mg, MgO, Ni, NiO, Au, and so forth. The second layer 13 is formed e.g. by sputtering in a thickness t2 of 50 to 100 nm.

The third layer 14 is formed on the second layer 13 in a shape of frame in a periphery corresponding to the individual organic EL display device. Firstly, the third layer 14 is formed on the second layer 13 all over the mother glass substrate 11; after that it is patterned by etching. The third layer 14 has a strong adhesive strength with both the second layer 13 and the polyimide substrate 100; however, the adhesive strength with the second layer 13 is stronger than the adhesive strength with the polyimide substrate 100. The purpose is to make the third layer 14 remain on the second layer 13 after peeling off of the organic EL display device.

As shown in FIG. 5, AlO, SiN, ITO, Cr, Ti and so forth are used for the third layer 14. The third layer 14 is formed by e.g. sputtering in a thickness t3 of 10 to 50 nm. The third layer 14 has a role to fix the polyimide substrate 100 to the mother glass substrate 11 during the manufacturing process, thus, certain adhesive strength with the polyimide substrate 100 is necessary; this adhesive strength depends on the line width w of the third layer 14. The line width w is e.g. 0.1 to 5 mm.

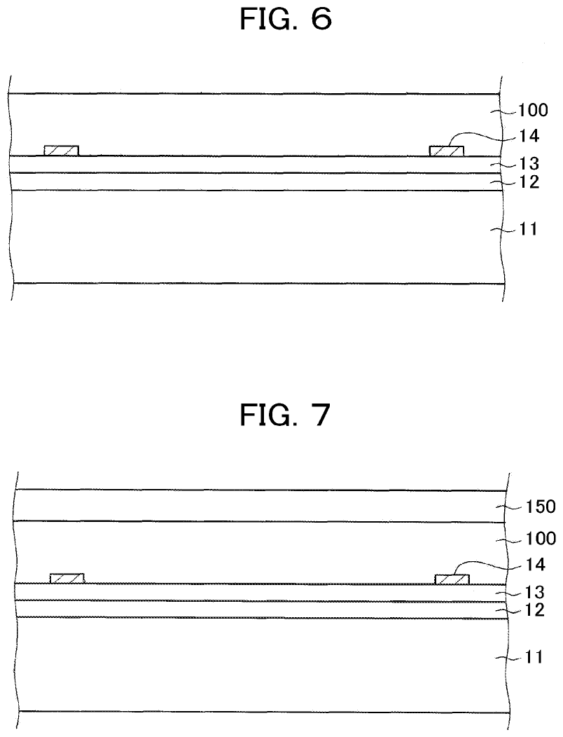

FIG. 6 is a cross sectional view in which the TFT substrate 100, namely, the polyimide substrate 100, is formed on the mother substrate 10 shown in FIGS. 3 and 4. The poly imide substrate 100 is formed in a thickness of 10 to 20 microns after the baking by manufacturing process explained with FIG. 2. As shown in FIG. 2, the organic undercoat 101, the TFT layer, the organic EL layer 113, protective layer 115 are formed in this order on the polyimide substrate 100.

FIG. 7 is a cross sectional view in which the organic EL array layer 150, which constitutes the organic EL display device as shown in FIG. 2, is formed on the polyimide substrate 100. The organic EL array layer 150 includes the layers from the organic undercoat layer 101 through the protective film 115 as shown in FIG. 2. The polyimide substrate 100 and the mother substrate 10 must adhere to each other stably during the manufacturing process. This adhesive strength is maintained mainly by the third layer 14 formed between the polyimide substrate 100 and the mother substrate 10.

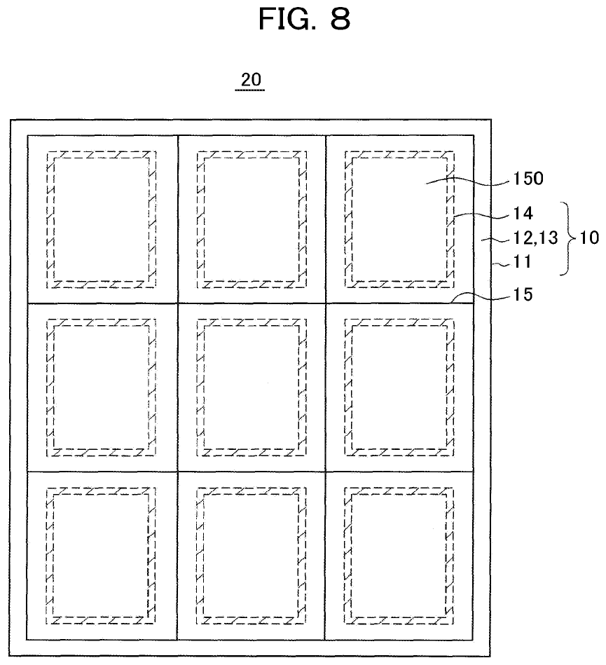

FIG. 8 is a plan view of the mother panel 20, in which a plurality of the organic EL display devices are formed on the mother substrate 10. In FIG. 8, the organic EL display device is represented by the organic EL array layer 150; the third layer (the second adhesive layer) 14, which provides the main adhesive strength between the polyimide substrate 100 and the mother substrate 10, is shown in broken lines.

In FIG. 8, the solid line 15 is a border between the individual organic EL display devices. Individual organic EL display devices are separated from the mother panel 20 along the line 15 by e.g. dicing. The third layer 14, formed on the mother substrate 10, is formed slightly inside, e.g. in a range up to 5 mm from the edge, namely, from the separating line 15.

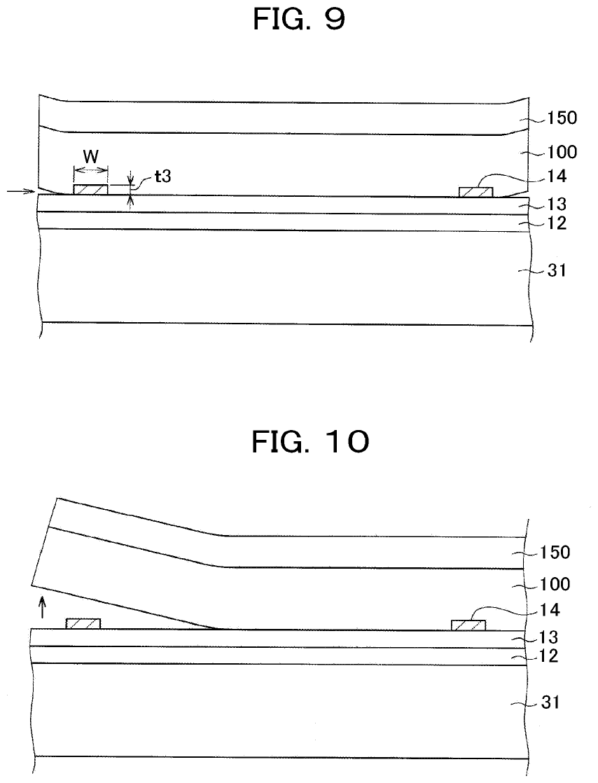

FIG. 9 is a cross sectional view of the organic EL display device, which is separated from the mother panel 20. In FIG. 9, the glass substrate 31 is separated from mother glass substrate 11 in a size of the individual organic EL display device. The first layer 12, the second layer 13 and the third layer 14 are formed on the glass substrate 31. The first layer 12 and second layer 13 are formed on all over the glass substrate 31; however, the third layer 14 is formed in frame like shape in a width of w along the periphery of the organic EL display device.

The polyimide substrate 100 is formed covering the second layer 13 and the third layer 14; the organic EL array layer 150 is formed on the polyimide substrate 100. Among them, the polyimide substrate 100 and the organic EL array layer 150 constitute the organic EL display device. The glass substrate 31, the first layer 12, the second layer 13 and the third layer 14 need to be removed from the polyimide substrate 100.

The feature of the present invention is that adhesive strength between the polyimide substrate 100 and the mother substrate 10 or glass substrate 31 is mainly maintained by the third layer 14. The second layer 13, which contact in large area with the polyimide substrate 100, has weak adhesive strength with the polyimide substrate 100, therefore, the second layer 13 is easily peeled off from the polyimide substrate 100. For example, the edge of the second layer 13 tends to peel off at the edge of the glass substrate 21 after the individual organic EL display device is separated from the mother panel 20. However, such a peel off at the edge of the glass substrate 31 occurs after the individual organic EL display device is separated from the mother substrate 20 by e.g. dicing; and such a peel off does not occur during the manufacturing process.

In the present invention, the organic EL display device is peeled off manually from the glass substrate 31 utilizing the peel off portion at the edge of the substrate as shown in FIG. 9. This process is depicted in FIG. 10. FIG. 10 is a cross sectional view in which the organic EL display device, which includes the polyimide substrate 100 and the organic EL array layer 150, is being peeled off from the glass substrate 31.

In FIG. 10, SiN is used for the first layer 12, Cu is used for the second layer 13 and AlO is used for the third layer 14. In FIG. 10, the glass substrate 31 and the SiN film 12 strongly adhere to each other; Cu film 13 adheres to the SiN film 12 strongly. However, the adhering strength between the Cu film 13 and the polyimide substrate 100 is weak; therefore, the polyimide substrate 100 is easily separated from the second layer 13, which is formed from Cu.

The patterned third layer 14 is formed from AlO; the adhering strength between the AlO film 14 and the polyimide substrate 100 is strong. Therefore, the adhering strength between the polyimide substrate 100 and the mother substrate 10 in the manufacturing process is mostly maintained by the third layer 14. On the other hand, the adhering strength between the AlO film 14 and the second layer 13 is strong. The adhesive strength between the AlO film 14 and the second layer 13, namely, the Cu film 13, is stronger than the adhesive strength between the A1O film 14 and the polyimide substrate 100; thus, adherence between the A1O film 14 and the Cu film 13 is maintained during the polyimide substrate 100 is being peeled off from the AlO film 14. Consequently, the polyimide substrate 100 is peeled off from the AlO film 14.

By the way, if the adhesive strength between the third layer 14 and the polyimide substrate 100 is too strong, they are difficult to be separated from each other. In contrast, if the adhesive strength between the third layer 14 and the polyimide substrate 100 is too weak, the third layer 14 and the polyimide substrate 100 are separated from each other during the manufacturing process. When the adhesive strength is evaluated by 90 degrees peel strength according to ASTM (American Society for Testing and Material) D1876-01, the adhesive strength between the polyimide substrate 100 and the Cu film 13, which is the second layer 13, is 0.01 to 0.1 N/cm. On the other hand, the adhesive strength between the polyimide substrate 100 and the AlO film 14, which is the third layer 14, is 2 to 4 N/cm, which is 40 to 200 times larger than the adhesive strength between the polyimide substrate 100 and the Cu film 13.

Therefore, most of the adhesive strength between the polyimide substrate 100 and the glass substrate 31 or the mother substrate 10 is maintained by adhesive strength between the polyimide substrate 100 and the third layer 14. The merit of the present invention is that the adhesive strength between the polyimide substrate 100 and the mother substrate 10 can be easily controlled by e.g. changing the width w of the third layer 14. The adhesive strength is proportional to the width w of the third layer 14, provided the pattern of the third layer 14 is fixed. If the width w of the third layer 14 can be changed from 0.1 to 5 mm, the adhesive strength can be controlled from 1 to 50 times.

Further, since the third layer 14 can be patterned by etching, the plan view of the third layer can be changed freely. Therefore, various shapes can be applicable to the third layer 14 considering the adhesive strength during the manufacturing process and peel off strength in the peel off process.

As described above, the first layer 12, the second layer 13 and the third layer 14 are not remained in the organic EL display device after the peel off. Since the influence of those layers is not visible to the human eyes, the commercial value is not deteriorated. In the microscopic view, however, a trance of the process remains on the bottom of the TFT substrate 100.

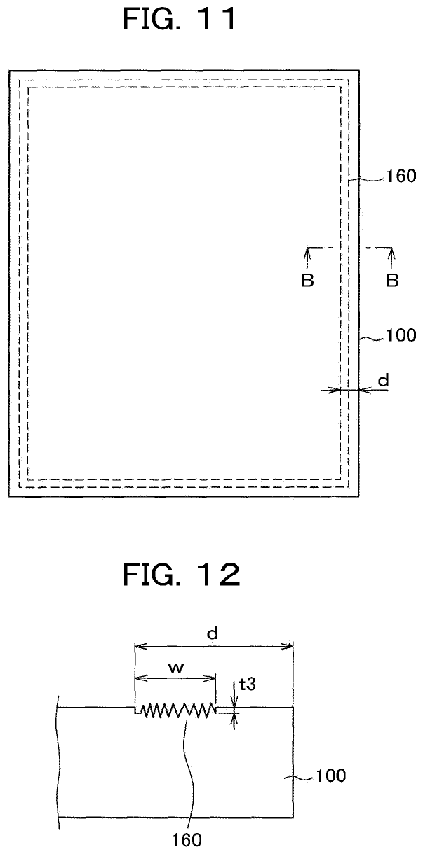

FIG. 11 is a bottom view of the completed organic EL display device. The frame shaped portion between the broken lines is the area where the third layer 14 has existed on the mother substrate 10. This place also corresponds to the position of the third layer 14 on the glass substrate 31 in FIG. 9. Since a thickness of the third layer 14 is 10 to 50 nm, outer shape of the polyimide substrate 100 is not changed at all considering a thickness of the polyimide substrate 100, which is 10 to 50 microns; however, in the microscopic view, recesses are remained in the area where the third layer 14 has existed.

In addition, since the adhesive strength of the third layer 14 with the polyimide substrate 100 is much stronger than the adhesive strength of the second layer 13 with polyimide substrate 100, a rough surface 160 is remained on the polyimide substrate 100 in the place where the third layer 14 has existed due to strong peel off stress. In other words, the surface roughness of the back side of the polyimide substrate 100 where the third layer 14 has contacted is larger than the surface roughness of the back side of the polyimide substrate 100 where the second layer 13 has contacted.

The surface roughness is defined by JIS (Japanese Industrial Standard); the roughness can be compared by any one of parameters Ra, Rz, and Rms. The surface roughness can be measured with surface roughness tester as SURFCOM or with atomic force microscope (AFM).

The surface roughness tester, however, is difficult to measure a roughness of the 10 to 50 nm, which correspond to a thickness of the third layer 14. In addition, the surface roughness tester is difficult to measure when the rate of the roughness is small. In such a case, the surface roughness can be measured with scanning electron microscope (SEM) or transmission electron microscope (TEM).

FIG. 12 is a cross sectional view of FIG. 11 along the line B-B. In FIG. 12, the recess of a depth of e.g. t3 is formed in the area of the back surface of the polyimide substrate 100 contacted with the third layer 14 on the mother substrate 10; the rough surface 160 is formed in the area the recesses are formed. The rough surface 160 is formed when the polyimide substrate 100 is peeled off from the third layer 14. The Roughness Ra is larger than a depth of the recess in the area the recesses are formed.

The inner area than the frame portion shown by broken lines is the area where the second layer 13 has existed in the mother substrate 10. Since the second layer 13 and the polyimide substrate 100 have contacted each other in this area, the ingredient of the second layer 13 diffuses into the polyimide substrate 100, consequently, a trace of the precipitated material is remained in the substrate 100. For example, when Cu is used for the second layer 13, cupper atoms diffuse into the polyimide substrate 100, and connect with oxygen to precipitate Cupper oxide. This precipitate can be detected by transmission electron microscopy (TEM); it is also detectable by component analysis using electron beam or X ray.

The notation d in FIGS. 11 and 12 defines the region in which the third layer 14 of the mother substrate 10 has contacted with the polyimide substrate 100, namely, a distance from the inner edge of the rough area 160 to the edge of the polyimide substrate 100. Generally, the value d is 5 mm or less.

Since a total thickness of the polyimide substrate 100 and the organic EL array layer 150 is 20 to 30 microns, the organic EL display device shown in FIG. 9 is not rigid; it is sometimes not easy to handle in the process after the glass substrate 31 is removed. In counter measure this problem, the supporting resin substrate 200 is sometimes attached on the organic EL array layer 150 through the adhesive 201.

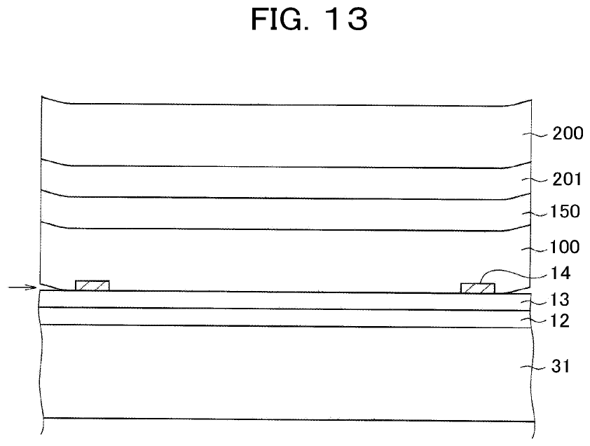

FIG. 13 is a cross sectional view that shows this structure. FIG. 13 is a cross sectional view of the organic EL display device, which is separated from the mother substrate 10 by dicing. Even in such a case, the structure of the first layer 12, the second layer 13 and the third layer 14 formed between the TFT substrate 100 and the glass substrate 31 is the same. A thickness of the supporting resin substrate 200 is e.g. 100 microns.

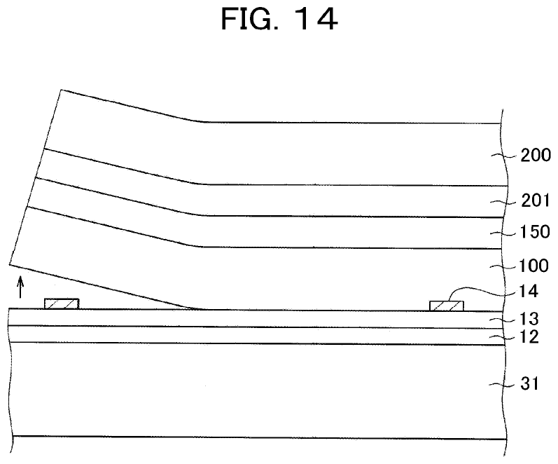

FIG. 14 is a cross sectional view in which the organic EL display device is being peeled off from the glass substrate 31, following the structure of FIG. 13. This process is the same as the peel off process explained in FIG. 10. The supporting resin substrate 200 can be removed if necessary after the peel off depicted in FIG. 14. By the way, the reflection of the external light deteriorates the display quality even in the case of organic EL display device. As the counter measure to this problem, a circular polarizing plate is sometimes set on the organic EL array layer 150 to suppress the reflection of the external light. In such a case the circular polarizing plate can be utilized to work as the supporting resin substrate 200.

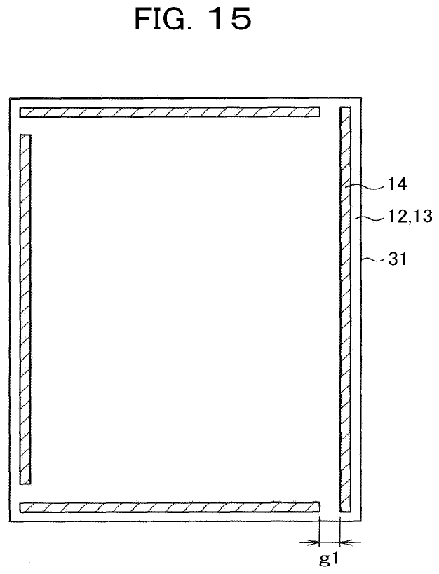

FIGS. 15 through 20 are plan views of the shapes of the third layer 14 formed on the mother substrate 10. In FIGS. 15 to 20, the explanation is made for the individual organic EL display device; however, the theory is the same for the mother substrate 10. It is common for the structures of FIGS. 15 to 20 that the first layer 12 and the second layer 13 are formed all over the glass substrate 31. The differences in FIGS. 15 to 20 are the structure of third layer 14. In the meantime, the materials for the first layer 12, the second layer 13 and the third layer 14 are the same as explained with FIG. 5 and so forth.

In the present invention, the adhesive strength between the third layer 14 and the polyimide substrate 100 can be flexibly determined not only by a width of the third layer 14 but also by a shape of a plan view of the third layer 14. The adhesive strength between the third layer 14 and the polyimide substrate 100 must take a balance between the adhesive strength required in the manufacturing process and easiness of peel off in the peel off process. The present invention can control the adhesive strength between the third layer 14 and the polyimide substrate 100 by changing the shape of a plan view of the third layer 14, thus, can provide a great flexibility in designing the organic EL display device.

In FIG. 15, the third layer 14 is formed along the sides of the organic EL display device; however, the third layer 14 is not a closed line, but has a gap g1 at the corners. A peeled portion tends to be generated between the polyimide substrate 100 and the glass substrate 31 at the corner when the organic EL display device is separated from the mother panel 20 by e.g. dicing; consequently, the organic EL display device can be easily peeled off from the glass substrate 31 using the peeled portion at the corner as the starting portion.

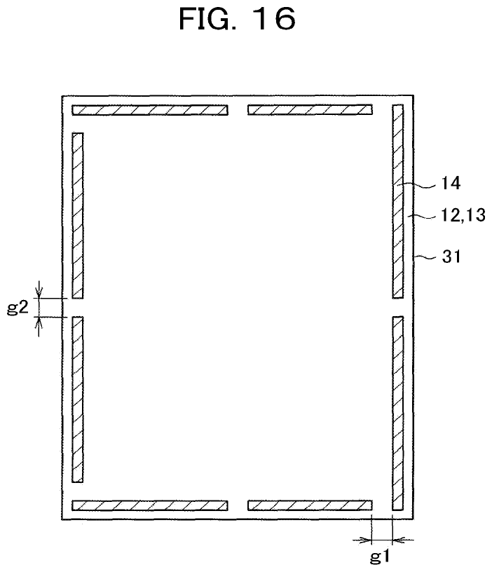

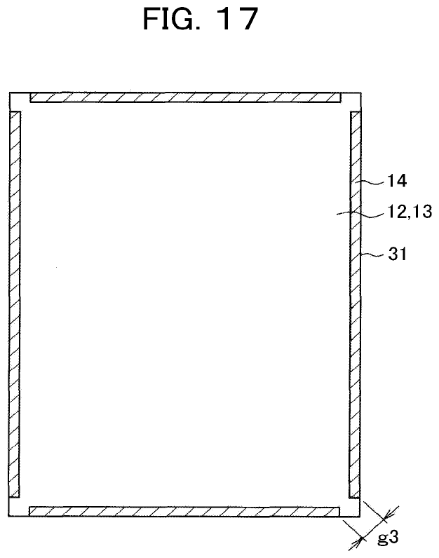

By the way, the gap g1 becomes an abnormal point; however, a thickness of the third layer 14 is 10 to 50 nm, and a thickness of the polyimide substrate 100 is 10 to 20 microns, therefore, this abnormal point does not raise a problem. It is the same in the cases of FIGS. 16 to 20.

FIG. 16 is an example of the third layer 14 having the gap g2 at the sides in addition to the gap g1 at the corners. The gaps g2 give a measure to take balance between the adhesive strength and easiness of peeling off.

FIG. 17 is an example of the third layer 14 being formed at the edge of the sides of the glass substrate 31. However, if the third layer is formed all along the edge of the sides, peeling off of the polyimide 100 from glass substrate 31 becomes difficult, thus, the gaps g3 are formed at the corners so that the organic EL display device can be peeled off from the glass substrate 39 at the corner.

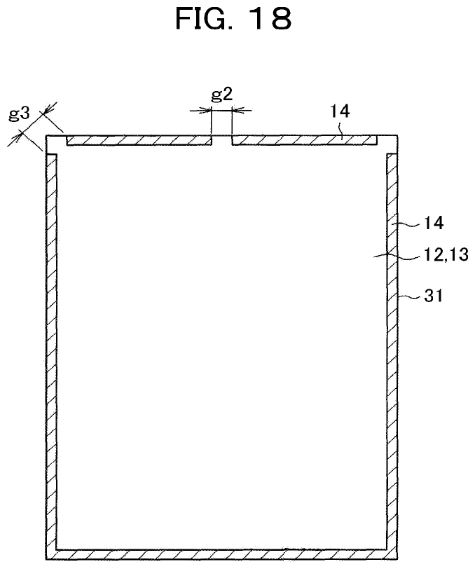

In FIG. 18, the third layer 14 is formed along the edge of the sides as FIG. 17, however, the gap g2 and the gap g3 are formed only at one side. Consequently, the peeling off portion of the edge of the polyimide substrate 100 tends to occur always at a specific side of the glass substrate 31. A peeling off of the polyimide substrate 100 from the glass substrate 31 can be performed using this peel off portion as the starting point.

The third layer 14 remains on the glass substrate 39, however it does not remain on the polyimide substrate 100 after the peeling off of the polyimide substrate 100 from the glass substrate 31. Even some traces of third layer 14 can be found by microscopic view or by some analysis, the trace is not visible for human eyes. Therefore, the third layer 14 can be formed in the display area. The adhesive strength between the polyimide substrate 100 and the glass substrate 31 can be more easily controlled by forming the third layer 14 in the display area.

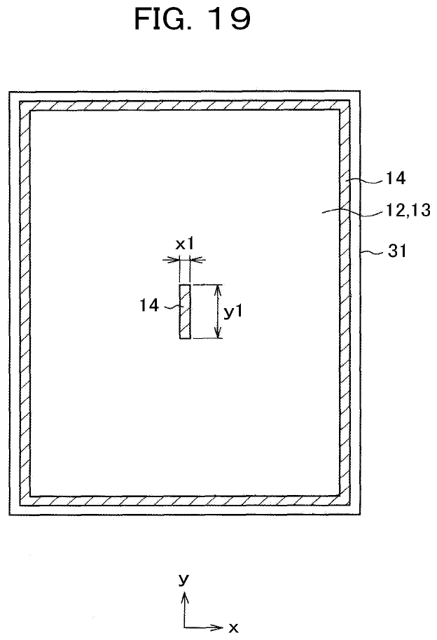

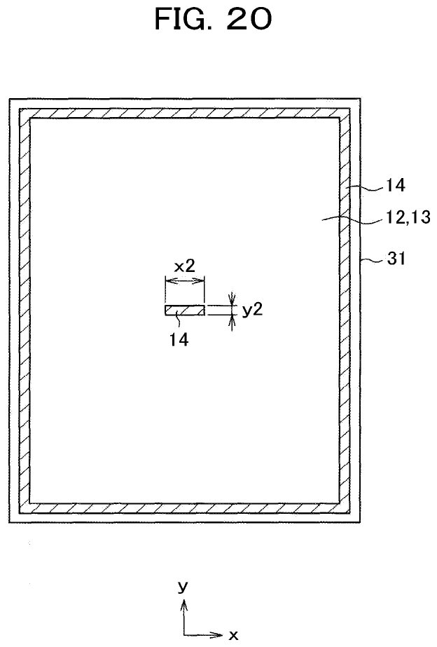

FIG. 19 shows an example of the third layer 14 being formed in a size of a width of x1 and a length of y1 at approximately the center of the display area of the organic EL display device. The balance between the adhesive strength and the easiness of peel off can be controlled by sizes of x1 and y1. FIG. 20 shows an example of the third layer 14 being formed in a size of a width of y2 and a length of x2 in approximately the center of display area of the organic EL display device. The balance between the adhesive strength and the easiness of pool off can be controlled by sizes of x2 and y2.

A shape of the third layer 14 is not limited by FIG. 19 or 20, but other shapes of the third layer 14 can be utilized and can be set at various places in the display area. In addition, a plurality of the third layers 14 can be formed in the display area.

What is claimed is:

1. A device having a resin substrate:
wherein the resin substrate has a surface, on which a functional layer is formed, and a back surface, which is rear side from the surface,
the back surface has a peripheral area and an inner area, which is located inner side than the peripheral area in a plan view,
the peripheral area has a rough surface whose surface roughness is larger compared with a surface roughness of the inner area.

2. The device according to claim 1,
wherein the rough surface is formed along the sides of the resin substrate.

3. The device according to claim 1,
wherein the rough surface is formed within a range of 5 mm or less from an edge of the resin substrate.

4. The display device according to claim 3,
wherein the resin substrate is polyimide substrate.

5. A manufacturing method of a device having a resin substrate including:
forming a first layer, which is made of metal or metal oxide on a glass substrate,
forming a second layer, which is made of metal or metal oxide, on the first layer,
forming a third layer, which is made of metal or metal oxide, on the second layer,
patterning the third layer,
forming a resin substrate on the third layer,
forming a functional layer on the resin substrate,
after that, peeling off the resin substrate from the second layer and the third layer.

6. The manufacturing method of the device having the resin substrate according to claim 5,
wherein the second layer is made of silicon oxide.

7. The manufacturing method of the device having the resin substrate according to claim 1,
wherein an adhesive strength between the third layer and the resin substrate is stronger than an adhesive strength between the second layer and the resin substrate.

8. The manufacturing method of the device having the resin substrate according to claim 5,
wherein an adhesive strength between the third layer and the second layer is stronger than an adhesive strength between the third layer and the resin substrate.

9. The manufacturing method of the device having the resin substrate according to claim 5,
wherein an adhesive strength between the first layer and the glass substrate is stronger than an adhesive strength between the third layer and the resin substrate.

10. The manufacturing method of the device having the resin substrate according to claim 5,
wherein the first layer is made of any one of SiN, ITO, and AlO.

11. The manufacturing method of the device having the resin substrate according to claim 5,
wherein the second layer is made of any one of Cu, CuO, Mg, MgO, Ni, NiO, and Au.

12. The manufacturing method of the device having the resin substrate according to claim 5,
wherein the third layer is made of any one of A10, SiN, ITO, Cr, and Ti.

13. The manufacturing method of the device having the resin substrate according to claim 5,
wherein the first layer is SiN, the second layer is Ni, and the third layer is AlO.

14. The manufacturing method of the device having the resin substrate according to claim 5,
wherein the resin substrate is polyimide substrate.

15. The manufacturing method of the device having the resin substrate according to claim 5,
wherein the glass substrate has a peripheral area and an inner area, which is formed inside of the peripheral area in a plan view,
the third layer is formed along the sides of the in the peripheral area.

16. The manufacturing method of the device having the resin substrate according to claim 15,
wherein the third layer is formed along 4 sides of the glass substrate in the peripheral area.

17. The manufacturing method of the device having the resin substrate according to claim 15,
wherein the third layer is formed in island shape in the display area.
